(19) United States
(12) Patent Application Publication
(10) Pub. No.: US 2026/0006794 A1
(43) Pub. Date: Jan. 1, 2026

(54) CAPACITOR, METHOD OF MANUFACTURING THE CAPACITOR, ELECTRONIC DEVICE INCLUDING THE CAPACITOR, AND METHOD OF MANUFACTURING THE ELECTRONIC DEVICE

(71) Applicants: SK hynix Inc., Icheon-si (KR); INDUSTRY-UNIVERSITY COOPERATION FOUNDATION HANYANG UNIVERSITY ERICA CAMPUS, Ansan-si (KR)

(72) Inventors: Jeongyeop Lee, Icheon-si (KR); Jiwon Moon, Icheon-si (KR); Namgue Lee, Icheon-si (KR); Ji-Hoon Ahn, Ansan-si (KR); Ji-Min Lee, Ansan-si (KR)

(21) Appl. No.: 19/249,864

(22) Filed: Jun. 25, 2025

(30) Foreign Application Priority Data
Jun. 28, 2024 (KR) 10-2024-0085753

(51) Int. Cl. H10B 53/30

(52) U.S. Cl. CPC H10B 53/30

(57) ABSTRACT

Disclosed are capacitors, methods of manufacturing the capacitors, electronic devices including the capacitors, and methods of manufacturing the electronic devices. A capacitor may include a first electrode, a second electrode disposed spaced apart from the first electrode, and a laminated film disposed between the first electrode and the second electrode, wherein the laminated film comprises: a HfₓZr₁₋ₓO_{y} layer, wherein x satisfies 0≤x≤1, y satisfies 1.5<y≤2 and a Bi₂O₃ layer disposed in one or more of: a region between the first electrode and the HfₓZr₁₋ₓO_{y} layer; a region between the second electrode and the HfₓZr₁₋ₓO_{y} layer; and an intermediate region of the HfₓZr₁₋ₓO_{y} layer in a direction in which the first and second electrodes are spaced apart each other.

### CROSS-REFERENCES TO RELATED APPLICATION

The present application claims, under 35 U.S.C. § 119a, the benefit of Korean Patent Application No. 10-2024-0085753, filed on Jun. 28, 2024 which is herein incorporated by reference in its entirety.

### BACKGROUND

### 1. Field

The present disclosure relates to electrical elements, devices including such elements, and methods of manufacturing them, and more particularly to capacitors, methods of manufacturing the capacitors, electronic devices including the capacitors, and methods of manufacturing the electronic devices.

### 2. Description of the Related Art

Advances in semiconductor manufacturing process technology have accelerated the scaling reduction of integrated circuits (ICs). Even in dynamic random access memory (DRAM), a representative semiconductor device, the area occupied by capacitors, the basic components of memory cells, is gradually decreasing. However, despite the reduction in area, it is necessary to secure a certain level of capacitance for a capacitor in consideration of performance, lifetime, error margin, etc. during device operations. In this regard, the development of high-dielectric constant materials, i.e., high-k materials, and continuous performance improvement related to capacitors are required to maintain the capacitance of capacitors.

However, high-dielectric constant materials have the disadvantage of relatively large leakage current. Among high dielectric constant materials, zirconium oxide (ZrO₂) and hafnium oxide (HfO₂) may have high permittivity of 40 and 70, respectively, when they have a tetragonal structure. Although doping ZrO₂ thin films with Al and Y has been reported to reduce the leakage current, there are limitations and challenges in improving the properties. Therefore, it is necessary to study the improvement of electrical properties that may simultaneously improve dielectric properties and leakage current properties by using various dopants or applying interfacial buffer layers.

In order to enhance the charge storage capability of ultra-fine semiconductor devices, attempts have been made to reduce the thickness of a dielectric film. However, since reducing the thickness of the dielectric film increases the leakage current due to tunneling, it is necessary to propose methods to improve the dielectric properties or leakage current properties of the dielectric film itself. On the other hand, in the ZrO₂/Al₂O₃/ZrO₂ structure, while the leakage current is improved with increasing Al content, but the dielectric properties are reduced due to reduced crystallinity. Therefore, methods that may simultaneously improve both dielectric and leakage current properties are required. Further research and development is required to reduce the flow of leakage current through grain boundaries.

### SUMMARY

An objective of embodiments of the present disclosure is to provide a capacitor and a method for manufacturing the same, which can improve the dielectric properties, such as the dielectric constant, of a dielectric layer for a capacitor while simultaneously reducing leakage current.

In addition, an objective of embodiments of the present disclosure is to provide a capacitor and a method for manufacturing the same, which can reduce leakage current by curing defects at the grain boundaries of an electrode or dielectric layer, and can increase the dielectric constant by inducing stress in the grains between the dielectric layer and the electrode.

In addition, an objective of embodiments of the present disclosure is to provide an electronic device, such as a memory device, including the aforementioned capacitor and a method for manufacturing the same.

The problems intended to be solved by the present disclosure are not limited to those mentioned above, and other problems will be apparent to those skilled in the art from the following description.

According to one embodiment of the present disclosure, a capacitor comprising: a first electrode; a second electrode disposed spaced apart from the first electrode; and a laminated film disposed between the first electrode and the second electrode, wherein the laminated film comprises an HfₓZr₁₋ₓO_{y} layer wherein x satisfies 0≤x≤1 and y satisfies 1.5<y≤2; and a Bi₂O₃ layer disposed in one or more of: a region between the first electrode and the HfₓZr₁₋ₓO_{y} layer; a region between the second electrode and the HfₓZr₁₋ₓO_{y} layer, and an intermediate region of the HfₓZr₁₋ₓO_{y} layer in a direction in which the first and second electrodes are spaced apart each other. The HfₓZr₁₋ₓO_{y} layer may have a structure selected from the group consisting of: a monolayer of Zr oxide, a monolayer of Hf oxide, a mixed layer including Zr oxide and Hf oxide, and a laminated structure in which Zr oxide and Hf oxide layers are alternately stacked.

The Bi₂O₃ layer may have a thickness in the range of about 0.001 to 3 nm.

The laminated film may have a thickness in the range of about 3 to 30 nm.

When the HfₓZr₁₋ₓO_{y} layer may include a first HfₓZr₁₋ₓO_{y} layer disposed in contact with or adjacent to the first electrode and a second HfₓZr₁₋ₓO_{y} layer disposed in contact with or adjacent to the second electrode, and the Bi₂O₃ layer may be disposed between the first and second HfₓZr₁₋ₓO_{y} layers.

The Bi₂O₃ layer may be configured to reduce oxygen vacancies in the HfₓZr₁₋ₓO_{y} layer.

The Bi₂O₃ layer may be configured to increase a dielectric constant of the HfₓZr₁₋ₓO_{y} layer.

According to another embodiment of the present disclosure, there is provided a memory device comprising the aforementioned capacitor as a data storage member.

The memory device may be a dynamic random access memory DRAM.

According to another embodiment of the present disclosure, a capacitor, comprising: a first electrode; a second electrode disposed spaced apart from the first electrode; and a HfₓZr₁₋ₓO_{y} layer disposed between the first electrode and the second electrode, wherein x satisfies 0≤x≤1, and y satisfies 1.5<y≤2, and wherein Bi oxide is present in one or both of: a first region of the first electrode that is in contact with or adjacent to the HfₓZr₁₋ₓO_{y} layer, and a second region of the HfₓZr₁₋ₓO_{y} layer that is in contact with or adjacent to the second electrode, and wherein the Bi oxide is disposed along a grain boundary within one or both of the first and second regions.

The HfₓZr₁₋ₓO_{y} layer may have a structure selected from the group consisting of: a monolayer of Zr oxide, a monolayer of Hf oxide, a mixed layer including Zr oxide and Hf oxide, and a laminated structure in which Zr oxide and Hf oxide layers are alternately stacked.

The first region may have a thickness in the range of about 0.1 to 30 nm.

The second region may have a thickness in the range of 0.1 to 30 nm.

The Bi oxide may be configured to increase a dielectric constant of the HfₓZr₁₋ₓO_{y} layer.

According to another embodiment of the present disclosure, there is provided a memory device comprising the aforementioned capacitor as a data storage member.

The memory device may be a dynamic random access memory DRAM.

According to another embodiment of the present disclosure, a method of manufacturing a capacitor comprises: preparing a first electrode; forming a Bi oxide layer on the first electrode; performing annealing on the first electrode and the Bi oxide layer such that Bi oxide from the Bi oxide layer infiltrates into a boundary region of the first electrode along a grain boundary; removing at least a portion of the Bi oxide layer remaining on the first electrode after the annealing; and forming a HfₓZr₁₋ₓO_{y} layer over the first electrode comprising the infiltrated Bi oxide, wherein x satisfies 0≤x≤1, and y satisfies 1.5<y≤2; and forming a second electrode on the HfₓZr₁₋ₓO_{y} layer.

The annealing may be performed at a temperature of about 300 to 550° C. in an inert gas atmosphere.

The step of removing at least a portion of the Bi oxide layer may be performed by an atomic layer etching (ALE) process.

The method of manufacturing the capacitor may further comprise the step of performing a heat treatment on the laminated structure comprising at least the first electrode and the HfₓZr₁₋ₓO_{y} layer, either before or after the step of forming a second electrode.

According to another embodiment of the present disclosure, a method of manufacturing a capacitor comprises the steps of providing a first electrode; forming a HfₓZr₁₋ₓO_{y} layer on the first electrode, wherein x satisfies 0≤x≤1, and y satisfies 1.5<y≤2 on the HfₓZr₁₋ₓO_{y} layer; forming a Bi oxide layer on the HfₓZr₁₋ₓO_{y} layer; and performing annealing on the HfₓZr₁₋ₓO_{y} layer and the Bi oxide layer such that the Bi oxide from the Bi oxide layer infiltrates into a boundary region of the HfₓZr₁₋ₓO_{y} layer along grain boundary; removing at least a portion of the Bi oxide layer remaining on the HfₓZr₁₋ₓO_{y} layer after the annealing; and forming a second electrode over the HfₓZr₁₋ₓO_{y} layer comprising the infiltrated Bi oxide.

The annealing may be performed at a temperature of about 300 to 550° C. in an inert gas atmosphere.

The step of removing at least a portion of the Bi oxide layer may be performed by an atomic layer etching (ALE) process.

The method of manufacturing the capacitor may further comprise the step of performing a heat treatment on a laminated structure comprising at least the first electrode and the HfₓZr₁₋ₓO_{y} layer, either before or after the step of forming a second electrode.

According to the embodiments of the present disclosure, it is possible to realize a capacitor that improves the dielectric properties, such as the dielectric constant, of a dielectric layer for a capacitor while reducing leakage current. According to one embodiment, the dielectric constant may be increased by improving the crystallinity of the dielectric layer, e.g., HfₓZr₁₋ₓO_{y} layer, through the insertion of the Bi₂O₃ material. Additionally, the leakage current characteristics may be improved by reducing oxygen vacancies in the HfₓZr₁₋ₓO_{y} layer using the Bi₂O₃ material.

In addition, according to the embodiments of the present disclosure, it is possible to realize a capacitor that reduces leakage current by curing defects at the grain boundaries of electrodes or dielectric layers, while also increasing permittivity by inducing stress in grains between the dielectric layers and the electrodes. According to one embodiment, Bi oxide may infiltrate into the surface portion of the electrode or the surface portion of the HfₓZr₁₋ₓO_{y} layer to cure defects in the grain structure and to induce stress in the grains at the interface between the electrode and the dielectric layer, thereby achieving both reduced leakage current and enhanced dielectric constant.

According to the embodiments of the preset disclosure, the capacitors may be usefully applied to electronic devices, such as memory devices including DRAM, to improve both integration density and device performance.

However, the effects of the present disclosure are not limited to the above effects, and may be extended in various ways without departing from the technical spirit and scope of the present disclosure.

### BRIEF DESCRIPTION OF THE DRAWINGS

FIG. 1 illustrates a cross-sectional view of a capacitor according to one embodiment of the present disclosure.

FIG. 2 illustrates a cross-sectional view of a capacitor according to another embodiment of the present disclosure.

FIG. 3 illustrates a cross-sectional view of a capacitor according to another embodiment of the present disclosure.

FIG. 4 illustrates a cross-sectional view of a capacitor according to another embodiment of the present disclosure.

FIG. 5 is a cross-sectional view illustrating a capacitor according to another embodiment of the present disclosure.

FIG. 6 illustrates a cross-sectional view of a capacitor according to another embodiment of the present disclosure.

FIG. 7 illustrates a flowchart for manufacturing a capacitor according to one embodiment of the present disclosure.

FIG. 8 is a graph illustrating an ALD process sequence for forming a HfₓZr₁₋ₓO_{y} layer, which may be applicable to a method of manufacturing a capacitor according to one embodiment of the present disclosure.

FIG. 9 is a graph illustrating an ALD process sequence for forming a HfₓZr₁₋ₓO_{y} layer, which may be applicable to a method of manufacturing a capacitor according to another embodiment of the present disclosure.

FIG. 10 is a graph illustrating an ALD process sequence for forming a Bi₂O₃ layer, which may be applied to a method of manufacturing a capacitor according to one embodiment of the present disclosure.

FIGS. 11A and 11B are graphs showing the results of evaluating the electrical characteristics of capacitors, according to embodiments of the present disclosure and comparative examples, before heat treatment.

FIGS. 12A and 12B are graphs showing the results of evaluating the electrical characteristics of capacitors, according to embodiments of the present disclosure and comparative examples, after heat treatment.

FIGS. 13A and 13B are graphs showing the results of evaluating the electrical characteristics of capacitors, according to embodiments of the present disclosure and comparative examples, before heat treatment.

FIGS. 14A and 14B are graphs showing the results of evaluating the electrical characteristics of capacitors, according to embodiments of the present disclosure and comparative examples, after heat treatment.

FIGS. 15A through 15D are graphs showing the results of an X-ray photoelectron spectroscopy (XPS) analysis of a dielectric layer applied to a capacitor according to embodiments of the present disclosure and comparative examples.

FIG. 16 is a graph showing a ratio of oxygen vacancies to oxygen ions (O²⁻) in a dielectric layer applied to a capacitor according to embodiments of the present disclosure and comparative examples.

FIG. 17 illustrates a cross-sectional view of a capacitor according to another embodiment of the present disclosure.

FIG. 18 illustrates a cross-sectional view of a capacitor according to another embodiment of the present disclosure.

FIGS. 19A through 19D are cross-sectional views illustrating a method of fabricating a capacitor according to another embodiment of the present disclosure.

FIGS. 20A through 20D are cross-sectional views illustrating a method of fabricating a capacitor according to another embodiment of the present disclosure.

FIG. 21 is a diagram illustrating an exemplary configuration of a DRAM device to which a capacitor according to an embodiment of the present disclosure may be applied.

### DETAILED DESCRIPTION

Hereinafter, the embodiments of the present disclosure will now be described in detail with reference to the accompanying drawings.

The embodiments of the present disclosure described below are provided for the purpose of more clearly illustrating embodiments of the present disclosure to those having ordinary skill in the art, and the scope of embodiments of the present disclosure is not intended to be limited by the following embodiments, which may be modified in various other ways.

The terms used in this specification are intended to describe specific embodiments and are not intended to limit the present disclosure. Terms used herein in the singular form may include the plural form, unless the context clearly indicates otherwise. Furthermore, the terms “comprise” and/or “comprising” as used herein are intended to specify the presence of the mentioned shapes, steps, numbers, motions, absences, elements, and/or groups thereof, and are not intended to exclude the presence or addition of one or more other shapes, steps, numbers, motions, absences, elements, and/or groups thereof. Furthermore, as used herein, the term “connected” is intended to mean not only that certain elements are directly connected, but also that they are indirectly connected by the interposition of other elements between them.

Further, when the present disclosure refers to a member being located “on” another member, this includes not only when a member is abutting another member, but also when there is another member between the two members. As used herein, the term “and/or” includes any one of the enumerated items and any combination of one or more of them. In addition, the terms “about,” “substantially,” and the like as used in the disclosure are intended to mean at or near the range of numbers or degrees, taking into account inherent manufacturing and material tolerances, and to prevent infringers from taking unfair advantage of the disclosure where precise or absolute numbers are stated, which are provided for the purpose of illustration.

Embodiments of the present disclosure will now be described in detail with reference to the accompanying drawings. The sizes or thicknesses of the areas or parts shown in the accompanying drawings may be somewhat exaggerated for clarity and ease of description. Throughout the detailed description, like reference numerals designate like components.

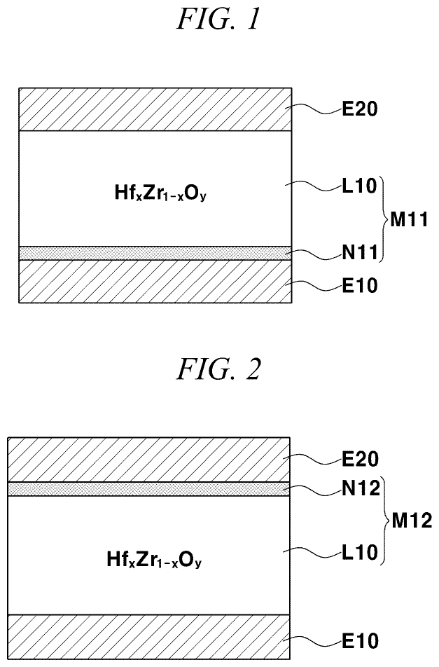

FIG. 1 illustrates a cross-sectional view of a capacitor according to one embodiment of the present disclosure.

Referring to FIG. 1, the capacitor may include a first electrode E10, a second electrode E20 disposed spaced apart from the first electrode E10, and a laminated film M11 disposed between the first electrode E10 and the second electrode E20 in a stacking direction. The laminated film M11 may include an HfₓZr₁₋ₓO_{y} layer L10, wherein x may satisfy 0≤x≤1 and y may satisfy 1.5<y≤2. The laminated film M11 may further include a Bi₂O₃ layer N11. The Bi₂O₃ layer N11 may be disposed between the first electrode E10 and the HfₓZr₁₋ₓO_{y} layer L10. in the stacking direction. According to one example, the first electrode E10 may be a lower electrode and the second electrode E20 may be an upper electrode. The Bi₂O₃ layer N11, the HfₓZr₁₋ₓO_{y} layer L10, and the second electrode E20 may be sequentially disposed on the first electrode E10 in the stacking direction.

The HfₓZr₁₋ₓO_{y} layer L10 may be a high-k material layer. For example, the HfₓZr₁₋ₓO_{y} layer L10 may have at least one of an orthorhombic crystal phase or a tetragonal crystal phase, and may exhibit at least one of ferroelectric properties or anti-ferroelectric properties. The HfₓZr₁₋ₓO_{y} layer L10 may have one of the following structures: a monolayer of Zr oxide, a monolayer of Hf oxide, a mixed layer of Zr oxide and Hf oxide, and a multilayer structure in which Zr oxide and Hf oxide layers are alternately stacked. The HfₓZr₁₋ₓO_{y} layer L10 may include at least one of Zr oxide, Hf oxide, HfZr oxide, or a mixture of Zr oxide and Hf oxide. For example, the HfₓZr₁₋ₓO_{y} layer L10 may be represented by HfₓZr₁₋ₓO₂, where x may satisfy 0≤x≤1. However, y is not limited to 2, and may satisfy, for example, 1.5<y≤2. The HfₓZr₁₋ₓO_{y} layer L10 may have a thickness of a few nm to tens of nm. As a non-limiting example, the HfₓZr₁₋ₓO_{y} layer L10 may have a thickness in the range of about 2 nm to 30 nm.

The Bi₂O₃ layer N11 is a type of Bi oxide layer, which may be a dielectric material layer. The Bi₂O₃ layer N11 may have an electrical conductivity that is comparable to or lower than the electrical conductivity of a typical semiconductor. The Bi₂O₃ layer N11 may have a small thickness. For example, the Bi₂O₃ layer N11 may have a thickness in the range of about 0.001 nm to 3 nm. The laminated film M11 including the Bi₂O₃ layer N11 and the HfₓZr₁₋ₓO_{y} layer L10 may have a thickness in the range of about 3 nm to 30 nm, as a non-limiting example. Since both the Bi₂O₃ layer N11 and the HfₓZr₁₋ₓO_{y} layer L10 may be metal oxides, the laminated film M11 may be a metal oxide layer.

The first electrode E10 may be formed of, for example, titanium nitride (TiN), tantalum nitride (TaN), ruthenium (Ru), ruthenium oxide (RuO₂), strontium ruthenium oxide (SrRuO₃), tungsten (W), tungsten nitride (WNₓ), molybdenum (Mo), molybdenum nitride (MₒNₓ), molybdenum oxide (MₒOₓ), platinum (Pt), or at least one other suitable conductive material. The first electrode E10 may include a metal or two or more alloys. For example, the first electrode E10 may include TiN or be formed entirely from TiN. However, the material of the first electrode E10 is not limited to the foregoing and may vary, as the case may be.

Similar to the first electrode E10, the second electrode E20 may be formed of, for example, titanium nitride (TiN), tantalum nitride (TaN), ruthenium (Ru), ruthenium oxide (RuO₂), strontium ruthenium oxide (SrRuO₃), tungsten (W), tungsten nitride (WNₓ), molybdenum (Mo), molybdenum nitride (MₒNₓ), molybdenum oxide (MₒOₓ), platinum (Pt), or the like. The second electrode E20 may include a metal or two or more alloys. For example, the second electrode E20 may include TiN or be formed entirely from TiN. However, the material of the second electrode E20 is not limited to the above, and may vary in some cases. In addition, each of the first electrode E10 and the second electrode E20 may have a monolayer structure or a multilayer structure.

FIG. 2 illustrates a cross-sectional view of a capacitor according to another embodiment of the present disclosure.

Referring to FIG. 2, the capacitor may include a first electrode E10, a second electrode E20 disposed spaced apart from the first electrode E10, and a laminated film M12 disposed between the first electrode E10 and the second electrode E20 in a stacking direction. The laminated film M12 may include an HfₓZr₁₋ₓO_{y} layer L10, wherein x may satisfy 0≤x≤1 and y may satisfy 1.5<y≤2. The laminated film M12 may further include a Bi₂O₃ layer N12 disposed between the second electrode E20 and the HfₓZr₁₋ₓO_{y} layer L10 in the stacking direction. The thickness conditions of each of the Bi₂O₃ layer N12, the HfₓZr₁₋ₓO_{y} layer L10, and the laminated film M12 may be the same as those described with reference to FIG. 1.

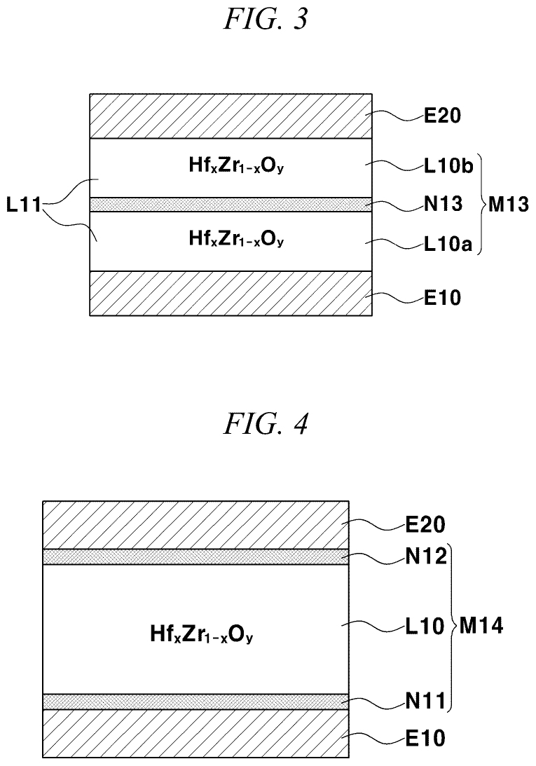

FIG. 3 illustrates a cross-sectional view of a capacitor according to another embodiment of the present disclosure.

Referring to FIG. 3, the capacitor may include a first electrode E10, a second electrode E20 disposed spaced apart from the first electrode E10, and a laminated film M13 disposed between the first electrode E10 and the second electrode E20 in a stacking direction. The laminated film M13 may include an HfₓZr₁₋ₓO_{y} layer L11, wherein x may satisfy 0≤x≤1 and y may satisfy 1.5<y≤2. The laminated film M13 may further include a Bi₂O₃ layer N13 disposed in an intermediate region of the HfₓZr₁₋ₓO_{y} layer L11 in a direction in which the first and second electrodes E10 and E20 are spaced apart from each other.

The HfₓZr₁₋ₓO_{y} layer L11 may include a first HfₓZr₁₋ₓO_{y} layer L10a that is in contact with or adjacent to the first electrode E10, and a second HfₓZr₁₋ₓO_{y} layer L10b that is in contact with or adjacent to the second electrode E20. The Bi₂O₃ layer N13 may be disposed between the first and second HfₓZr₁₋ₓO_{y} layers L10a and L10b in the stacking direction. The Bi₂O₃ layer N13 may be referred to as an intermediate Bi₂O₃ layer. The first HfₓZr₁₋ₓO_{y} layer L10a may be disposed between the first electrode E10 and the Bi₂O₃ layer N13, and the second HfₓZr₁₋ₓO_{y} layer L10b may be disposed between the second electrode E20 and the Bi₂O₃ layer N13. The thicknesses of the first and second HfₓZr₁₋ₓO_{y} layers L10a and L10b may be the same, or one may be relatively thicker than the other. Accordingly, the distances from the Bi₂O₃ layer N13 to the first and second electrodes E10 and E20 may be the same or different from each other. The thickness condition of the Bi₂O₃ layer N13 may be the same as that described for the Bi₂O₃ layer N11 in FIG. 1. Similarly, the total thickness of the HfₓZr₁₋ₓO_{y} layer L11 (i.e., the combined thickness of L10a and L10b) may be the same as the thickness of the HfₓZr₁₋ₓO_{y} layer L10 described in FIG. 1. The thickness condition for the laminated film M13 may also be the same as that described for the laminated film M11 in FIG. 1.

In the embodiments of the present disclosure, the Bi₂O₃ layers N11, N12, and N13 may serve to simultaneously improve the dielectric properties and leakage current properties of the HfₓZr₁₋ₓO_{y} layers L10 and L11. The Bi₂O₃ layers N11, N12, and N13 may increase the dielectric constant of the HfₓZr₁₋ₓO_{y} layers L10 and L11 by improving the crystallinity of the HfₓZr₁₋ₓO_{y} layers L10 and L11. As a non-limiting example, the Bi₂O₃ layers N11, N12, and N13 may increase the permittivity of the HfₓZr₁₋ₓO_{y} layers L10 and L11 by about 12 to 20%. In addition, the Bi₂O₃ layers N11, N12, and N13 may reduce the leakage current of the HfₓZr₁₋ₓO_{y} layers L10 and L11 by reducing the oxygen vacancies in the HfₓZr₁₋ₓO_{y} layers L10 and L11. As a non-limiting example, the Bi₂O₃ layer N11, N12, or N13 may reduce the leakage current by about 0.5×10⁻¹ A/cm² or more. When the same dielectric layer is used, the effect of reducing the equivalent oxide thickness (EOT) by the insertion of the Bi₂O₃ layer N11, N12, or N13 may be achieved by about 0.09 nm to 0.14 nm, as a non-limiting example. Thus, the capacitor structure according to the embodiment of the present disclosure may provide a solution to a problem caused by the miniaturization of electronic/semiconductor devices, and may have characteristics advantageous for improving both integration density and device performance.

Two or more of Bi₂O₃ layers N11, N12, and N13 described in FIGS. 1 to 3 may be applied to a single capacitor. Examples of this are shown in FIGS. 4 to 6.

FIG. 4 illustrates a cross-sectional view of a capacitor according to another embodiment of the present disclosure.

Referring to FIG. 4, the capacitor may include a first electrode E10, a second electrode E20 disposed spaced apart from the first electrode E10, and a laminated film M14 disposed between the first electrode E10 and the second electrode E20 in a stacking direction. The laminated film M14 may include an HfₓZr₁₋ₓO_{y} layer L10, wherein x may satisfy 0≤x≤1 and y may satisfy 1.5<y≤2. The laminated film M14 may further include a first Bi₂O₃ layer N11 disposed between the first electrode E10 and the HfₓZr₁₋ₓO_{y} layer L10, and a second Bi₂O₃ layer N12 disposed between the second electrode E20 and the HfₓZr₁₋ₓO_{y} layer L10, in the stacking direction.

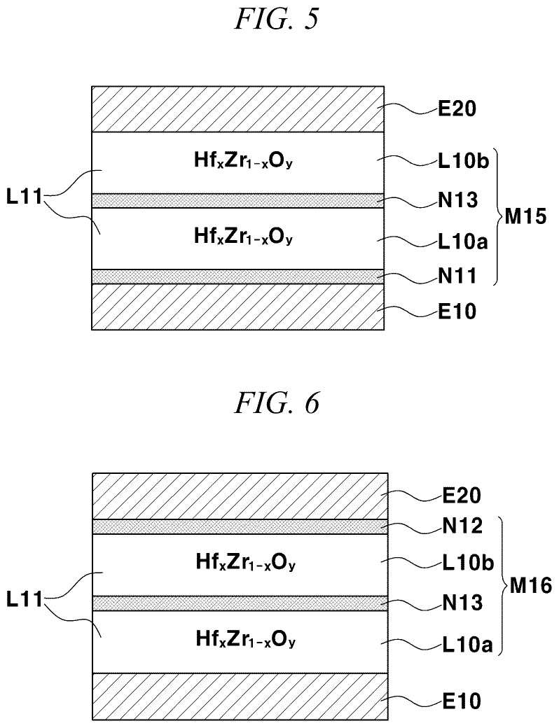

FIG. 5 illustrates a cross-sectional view of a capacitor according to another embodiment of the present disclosure.

Referring to FIG. 5, the capacitor may include a first electrode E10, a second electrode E20 disposed spaced apart from the first electrode E10, and a laminated film M15 disposed between the first electrode E10 and the second electrode E20 in a stacking direction. The laminated film M15 may include an HfₓZr₁₋ₓO_{y} layer L11, wherein x may satisfy 0≤x≤1 and y may satisfy 1.5<y≤2. The laminated film M15 may further include a first Bi₂O₃ layer N11 disposed between the first electrode E10 and the HfₓZr₁₋ₓO_{y} layer L11. In addition, the laminated film M15 may include a second Bi₂O₃ layer N13 disposed in an intermediate region of the HfₓZr₁₋ₓO_{y} layer L11 in the direction in which the first and second electrodes E10 and E20 are mutually spaced apart. In particular, the HfₓZr₁₋ₓO_{y} layer L11 includes a first HfₓZr₁₋ₓO_{y} layer L10a that is in contact with the Bi₂O₃ layer N11, and a second HfₓZr₁₋ₓO_{y} layer L10b that is in contact with or adjacent to the second electrode E20. The second Bi₂O₃ layer N13 is disposed between the first and second HfₓZr₁₋ₓO_{y} layers L10a and L10b in the stacking direction.

FIG. 6 illustrates a cross-sectional view of a capacitor according to another embodiment of the present disclosure.

Referring to FIG. 6, the capacitor may include a first electrode E10, a second electrode E20 disposed spaced apart from the first electrode E10, and a laminated film M16 disposed between the first electrode E10 and the second electrode E20 in a stacking direction. The laminated film M16 may include an HfₓZr₁₋ₓO_{y} layer L11, wherein x may satisfy 0≤x≤1 and y may satisfy 1.5<y≤2. The laminated film M16 may further include a first Bi₂O₃ layer N13 disposed in an intermediate region of the HfₓZr₁₋ₓO_{y} layer L11 in the direction in which the first and second electrodes E10 and E20 are spaced apart from each other. In particular, the HfₓZr₁₋ₓO_{y} layer L11 includes a first HfₓZr₁₋ₓO_{y} layer L10a that is in contact with the first electrode E10, and a second HfₓZr₁₋ₓO_{y} layer L10b that is adjacent to the second electrode E20. The first Bi₂O₃ layer N13 is disposed between the first and second HfₓZr₁₋ₓO_{y} layers L10a and L10b.

In addition, the laminated film M16 may include a second Bi₂O₃ layer N12 disposed between the second electrode E20 and the HfₓZr₁₋ₓO_{y} layer L11. In particular, the second Bi₂O₃ layer N12 is disposed between the second electrode E20 and the second HfₓZr₁₋ₓO_{y} layer L10b. In some cases, in the embodiment of FIG. 6, the laminated film M16 may further include a third Bi₂O₃ layer disposed between the first electrode E10 and the first HfₓZr₁₋ₓO_{y} layer L10a.

When two or more Bi₂O₃ layers are applied to a single capacitor, as shown in FIGS. 4 through 6, the beneficial effects of the Bi₂O₃ layer, such as increased dielectric constant, reduced leakage current, and reduced equivalent oxide thickness (EOT), may also be achieved. Moreover, when two or more Bi₂O₃ layers are applied at appropriate locations, these effects may be further enhanced.

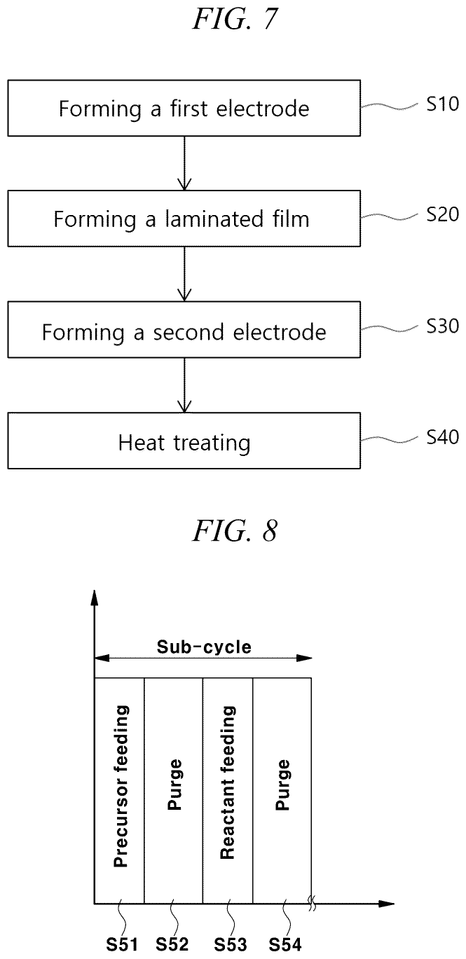

FIG. 7 is a flowchart illustrating a method of manufacturing a capacitor according to one embodiment of the present disclosure.

Referring to FIG. 7, the method may include a step S10 of forming a first electrode, a step S20 of forming a laminated film on the first electrode, and a step S30 of forming a second electrode on the laminated film. The laminated film may include a HfₓZr₁₋ₓO_{y} layer, wherein x may satisfy 0≤x≤1, and y may satisfy 1.5<y≤2. The laminated film may further include a Bi₂O₃ layer disposed in at least one of the following regions: between the first electrode and the HfₓZr₁₋ₓO_{y} layer, between the second electrode and the HfₓZr₁₋ₓO_{y} layer, or within an intermediate region of the HfₓZr₁₋ₓO_{y} layer in a direction in which the first and second electrodes are spaced apart each other. The method may further include a step S40 of heat treating a laminated structure including the first electrode, the laminated film, and the second electrode. In another embodiment, the heat treatment may be performed before the step S30 of forming the second electrode. In this case, the heat treatment may be performed on a laminated structure including the first electrode and the laminated film. The capacitor resulting from the method may have the structure described with reference to any of FIGS. 1 to 6.

The HfₓZr₁₋ₓO_{y} layer and the Bi₂O₃ layer may be deposited using atomic layer deposition (ALD), metal organic chemical vapor deposition (MOCVD), pulsed laser deposition (PLD), physical vapor deposition (PVD), or the like. The PVD process may include, as a non-limiting example, a sputtering process. In the formation (deposition) of the HfₓZr₁₋ₓO_{y} layer and the Bi₂O₃ layer, a reactant such as O₃, H₂O, O₂ plasma, or H₂O₂ may be used as the oxygen source (raw material). The laminated film may have a kind of multicomponent laminated structure. During the formation (deposition) of the HfₓZr₁₋ₓO_{y} layer and the Bi₂O₃ layer, the deposition temperature may be in the range of about 50 to 600° C.; however, other temperatures may also be used.

According to a non-limiting example, the HfₓZr₁₋ₓO_{y} layer and the Bi₂O₃ layer may be formed by an ALD process. At this time, CpZrNMe₃₂ may be used as a precursor for Zr, Bi(Et)₃ may be used as a precursor for Bi, and O₃ may be used as a reactant. However, the specific materials used for the Zr precursor, the Bi precursor, and the reactant may vary. A Zr oxide layer (e.g., a ZrO₂ layer) having a thickness of about 6 nm may be formed on the first electrode, and a Bi₂O₃ layer having a thickness of about 0.1 nm may be formed on at least one of lower, middle, or upper portions of the Zr oxide layer. However, the above thickness conditions are exemplary and may be adjusted as needed.

The heat treatment may be carried out before or after the formation of the second electrode, for example, at a temperature of about 1000° C. or lower. During the heat treatment, the HfₓZr₁₋ₓO_{y} layer may undergo at least partial crystallization, or its crystallinity may be enhanced.

FIG. 8 is a graph illustrating an ALD process sequence for forming a HfₓZr₁₋ₓO_{y} layer, which may be applicable to a method of manufacturing a capacitor according to one embodiment of the present disclosure.

Referring to FIG. 8, the step of forming the HfₓZr₁₋ₓO_{y} layer includes a step S51 of supplying a precursor for the formation of the HfₓZr₁₋ₓO_{y} layer into a chamber in which a first electrode is disposed, a step S52 of purging the chamber with a purge gas, a step S53 of supplying a reactant into the chamber, and a step S54 of purging the chamber with a purge gas. Here, the precursor for the formation of the HfₓZr₁₋ₓO_{y} layer may include at least one of a precursor for Zr or a precursor for Hf. The reactant may include at least one of O₃, H₂O, O₂ plasma, or H₂O₂. The steps S51, S52, S53, and S54 may constitute a sub-cycle, and the sub-cycle may be repeated a plurality of times.

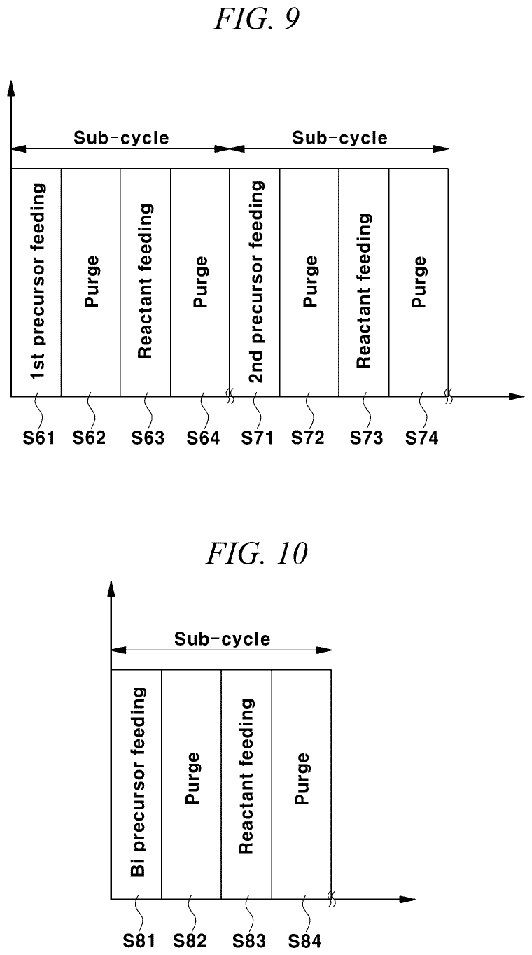

FIG. 9 is a graph illustrating an ALD process sequence for forming a HfₓZr₁₋ₓO_{y} layer, which may be applied to a method of manufacturing a capacitor according to another embodiment of the present disclosure.

Referring to FIG. 9, the step of forming the HfₓZr₁₋ₓO_{y} layer may include a step S61 of supplying a first precursor for the formation of the HfₓZr₁₋ₓO_{y} layer into a chamber in which a first electrode is disposed, a step S62 of purging the chamber with a purge gas, a step S63 of supplying a first reactant into the chamber, and a step S64 of purging the chamber with a purge gas. In addition, the step of forming the HfₓZr₁₋ₓO_{y} layer may include a step S71 of supplying a second precursor for the formation of the HfₓZr₁₋ₓO_{y} layer into the chamber, a step S72 of purging the chamber with a purge gas, a step S73 of supplying a second reactant into the chamber, and a step S74 of purging the chamber with a purge gas. Here, the first precursor may include any one of a precursor for Zr and a precursor for Hf, and the second precursor may include any other one of the precursor for Zr and the precursor for Hf. The first and second reactants may include any one of O₃, H₂O, O₂ plasma, and H₂O₂. The steps S61, S62, S63, and S64 may constitute a sub-cycle. The steps S71, S72, S73, and S74 may also constitute a sub-cycle. Each sub-cycle may be performed one or more times.

FIG. 10 is a graph illustrating an ALD process sequence for forming a Bi₂O₃ layer, which may be applicable to a method of manufacturing a capacitor according to one embodiment of the present disclosure.

Referring to FIG. 10, the step of forming the Bi₂O₃ layer may include a step S81 of supplying a precursor for Bi into a chamber for deposition, a step S82 of purging the chamber with a purge gas, a step S83 of supplying a reactant into the chamber, and a step S84 of purging the chamber with a purge gas. The reactant may include one of O₃, H₂O, O₂ plasma, and H₂O₂. The steps S81, S82, S83, and S84 may constitute a sub-cycle, and the sub-cycle may be performed one or more times.

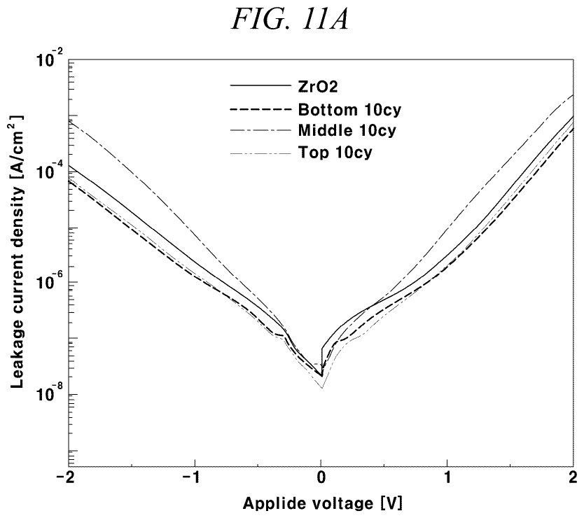

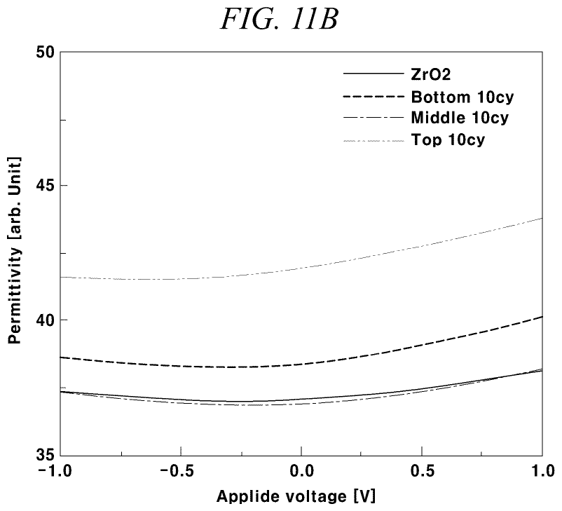

FIGS. 11A and 11B are graphs showing the results of evaluating the electrical characteristics of capacitors, according to embodiments of the present disclosure and comparative examples, before heat treatment. Here, the capacitors according to the embodiments have the structures of FIGS. 1, 2, and 3. In FIGS. 11A and 11B, the embodiment labeled “Bottom 10cy” corresponds to the structure of FIG. 1, wherein the Bi₂O₃ layer was formed through 10 cycles of ALD, and the HfₓZr₁₋ₓO_{y} layer is a ZrO₂ layer. The embodiment labeled “Top 10cy” corresponds to the structure of FIG. 2, wherein the Bi₂O₃ layer was formed through 10 cycles of ALD, and the HfₓZr₁₋ₓO_{y} layer is a ZrO₂ layer. The embodiment labeled “Middle 10cy” corresponds to the structure of FIG. 3, wherein the Bi₂O₃ layer is formed through 10 cycles of ALD, and the HfₓZr₁₋ₓO_{y} layer is a ZrO₂ layer. On the other hand, the comparative example labeled “ZrO₂” corresponds to the capacitor that uses a ZrO₂ monolayer as a dielectric film without a Bi₂O₃ layer. FIG. 11A shows the leakage current characteristic as a function of applied voltage, and FIG. 11B shows the permittivity characteristic as a function of applied voltage.

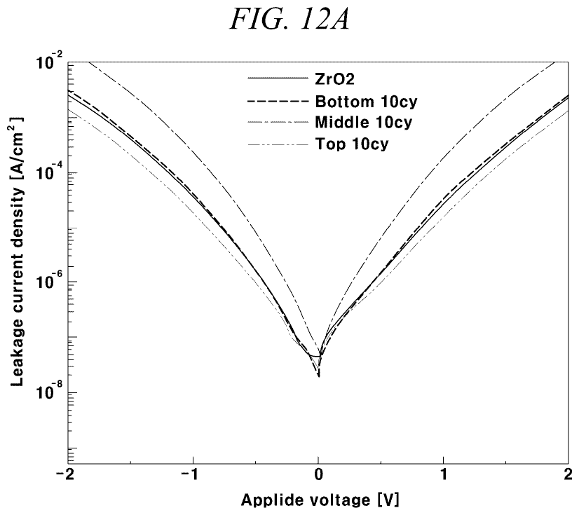

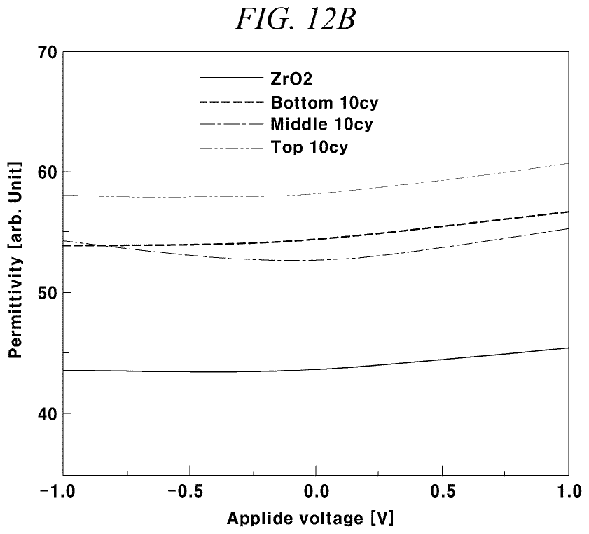

FIGS. 12A and 12B are graphs showing the results of evaluating the electrical characteristics of capacitors, according to embodiments and comparative examples of the present disclosure, after heat treatment. The embodiments and comparative examples are the same as those described in FIGS. 11A and 11B. FIG. 12A shows the leakage current characteristics as a function of applied voltage, and FIG. 12B shows the permittivity characteristics as a function of applied voltage.

Referring to FIGS. 11A, 11B, 12A, and 12B, the evaluation of the electrical properties, including permittivity-voltage and current-voltage characteristics, indicates that the Bi₂O₃/ZrO₂ stacked structure increases the permittivity by about 5 to 15 (corresponding to about 12-20%) and reduces the leakage current by more than about 0.5×10⁻¹ A/cm² at an operating voltage of a semiconductor device.

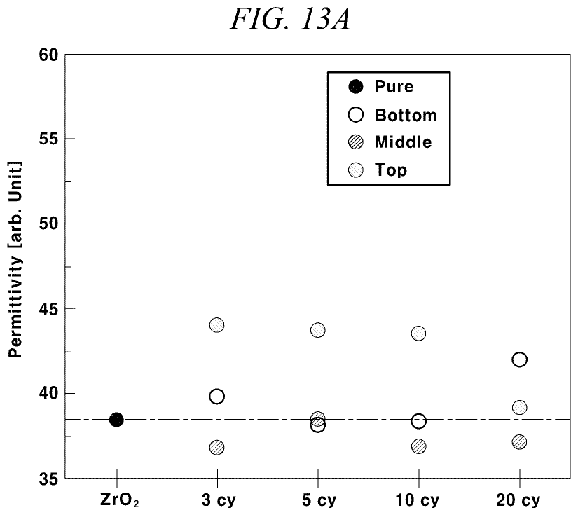

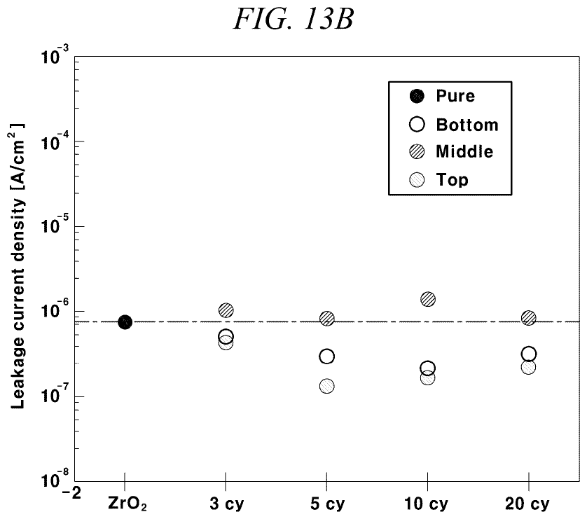

FIGS. 13A and 13B are graphs showing the results of evaluating the electrical characteristics of capacitors, according to embodiments of the present disclosure and comparative examples, before heat treatment. Here, the capacitors according to the embodiments have the structures of FIGS. 1, 2, and 3. In FIGS. 13A and 13B, the embodiment labeled “Bottom” has the structure of FIG. 1, wherein the HfₓZr₁₋ₓO_{y} layer is a ZrO₂ layer. The embodiment labeled “Top” has the structure of FIG. 2, wherein the HfₓZr₁₋ₓO_{y} layer is a ZrO₂ layer. The embodiment labeled “Middle” has the structure of FIG. 3, wherein the HfₓZr₁₋ₓO_{y} layer is a ZrO₂ layer. In the above embodiments, the number of deposition cycles for the Bi₂O₃ layer was varied to evaluate the resulting changes in electrical properties. The number of deposition cycles for the Bi₂O₃ layer may correspond to the thickness of the Bi₂O₃ layer. The Bi₂O₃ layer may be referred to as a kind of blocking layer. On the other hand, the capacitor according to the comparative example, labeled “Pure,” uses a ZrO₂ monolayer as a dielectric film without a Bi₂O₃ layer. FIG. 13A shows the permittivity characteristic, and FIG. 13B shows the leakage current characteristics.

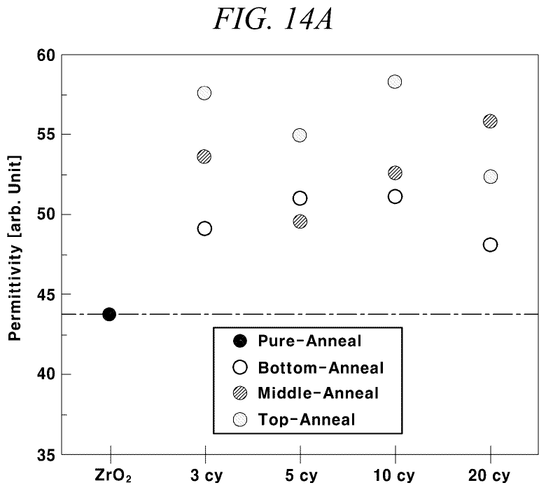

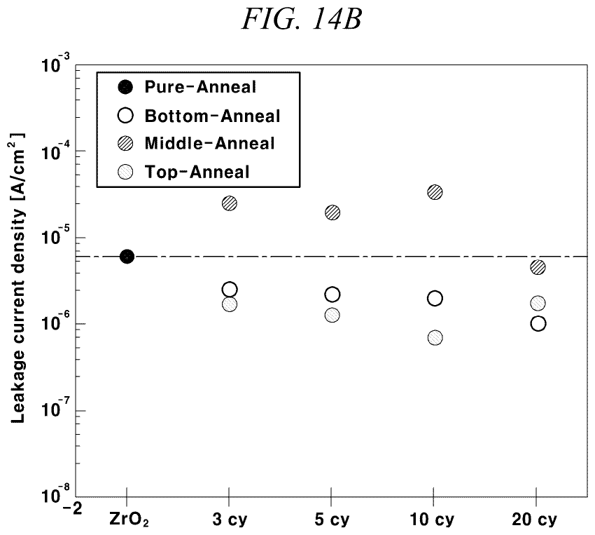

FIGS. 14A and 14B are graphs showing the results of evaluating the electrical characteristics of capacitors, according to embodiments of the present disclosure and comparative examples, after heat treatment. The embodiments and comparative examples are the same as those described with reference to FIGS. 13A and 13B. FIG. 14A shows the permittivity characteristics, and FIG. 14B shows the leakage current characteristics. The heat treatment was performed at a temperature of about 500° C. for about 30 seconds.

Referring to FIGS. 13A, 13B, 14A, and 14B, it may be seen that the insertion of the Bi₂O₃ layer increases the permittivity and decreases the leakage current.

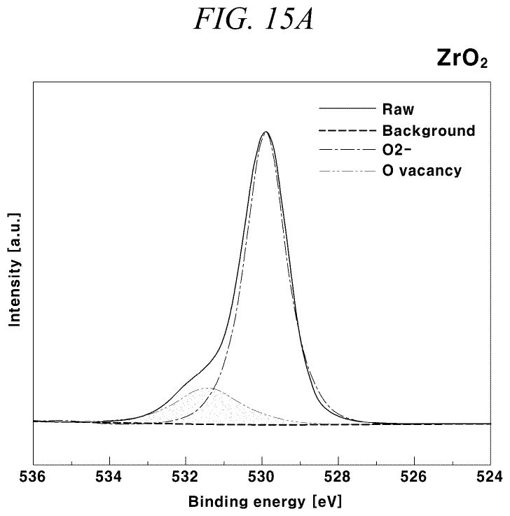

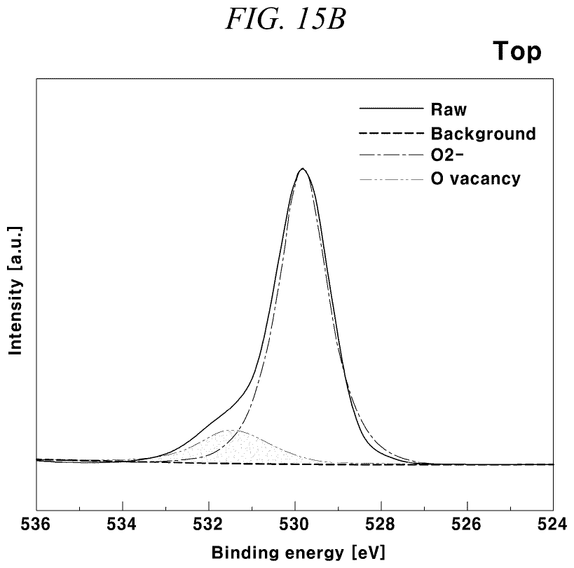

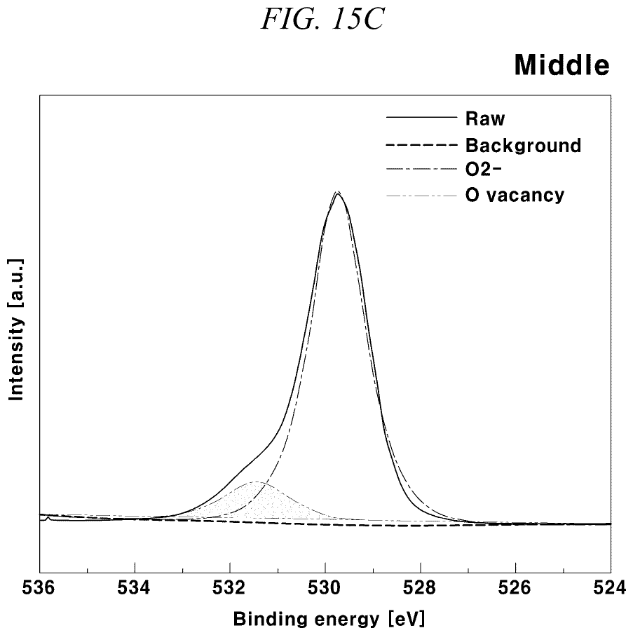

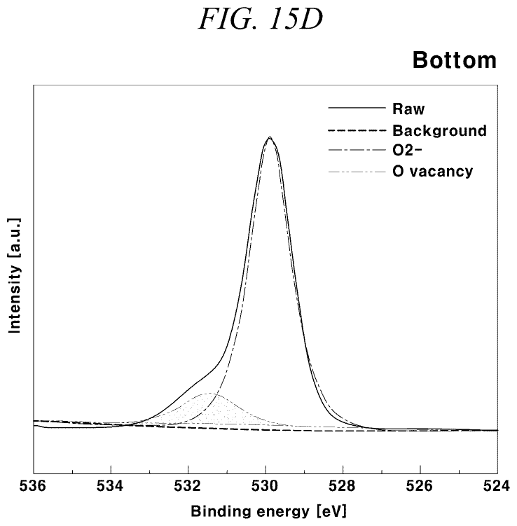

FIGS. 15A to 15D are graphs showing X-ray photoelectron spectroscopy (XPS) analysis results for dielectric layers applied to capacitors according to embodiments of the present disclosure and comparative examples. FIG. 15A shows the analysis results for a ZrO₂ thin film according to a comparative example that does not include a Bi₂O₃ layer. FIGS. 15B to 15D show analytical results for Bi₂O₃—ZrO₂ laminated films according to embodiments. FIG. 15B shows the analysis results for the dielectric layer corresponding to FIG. 2, FIG. 15C shows the analysis results for the dielectric layer corresponding to FIG. 3, and FIG. 15D shows the analysis results for the dielectric layer corresponding to FIG. 1. In all embodiments, the number of ALD deposition cycles for the Bi₂O₃ layer was 10. FIGS. 15A to 15D show the oxygen 1s XPS spectra.

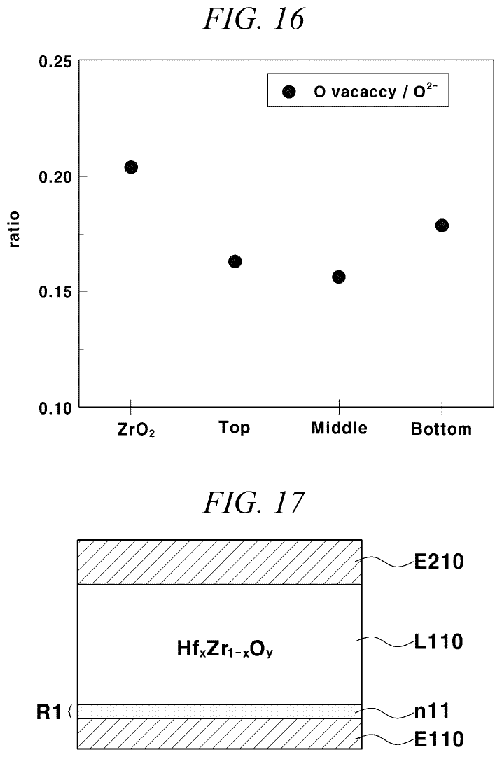

FIG. 16 is a graph based on the results of FIGS. 15A to 15D, showing the ratio of oxygen vacancies to oxygen ions (O²⁻ ions) in a dielectric layer applied to capacitors according to embodiments of the present disclosure and comparative examples.

Referring to FIG. 16, it may be seen that the ratio of oxygen vacancies to oxygen ions is reduced in the dielectric layer of the embodiments including the Bi₂O₃ layer, compared to the comparative example using only the ZrO₂ layer. For the comparative example using only the ZrO₂ layer, the ratio of oxygen vacancies to the O²⁻ ions is 20.4%. For the ‘Top’ embodiment, the ratio of oxygen vacancies to the O²⁻ ions is 16.3%. For the ‘Middle’ embodiment, the ratio of oxygen vacancies to the O²⁻ ions is 15.6%. For the ‘Bottom’ embodiment, the ratio of oxygen vacancies to the O²⁻ ions is 17.9%. It may be seen that the insertion of the Bi₂O₃ layer reduces the ratio of oxygen vacancies to the O²⁻ ions by about 2.5% to 4.8%. The oxygen vacancy content may be reduced by about 12 to 23%. When the Bi₂O₃ layer is applied, as in the embodiment, the oxygen vacancies in the HfₓZr₁₋ₓO_{y} layer may be reduced, thereby contributing to a reduction in leakage current. In addition, the insertion of the Bi₂O₃ layer may further reduce the equivalent oxide film thickness (EOT), for example, by about 0.09 nm to 0.14 nm, although this range is provided as a non-limiting example.

FIG. 17 illustrates a cross-sectional view of a capacitor according to another embodiment of the present disclosure.

Referring to FIG. 17, the capacitor may include a first electrode E110, a second electrode E210 disposed spaced apart from the first electrode E110, and an HfₓZr₁₋ₓO_{y} layer L110 disposed between the first electrode E110 and the second electrode E210, wherein x may satisfy 0≤x≤1, and y may satisfy 1.5<y≤2. A region hereinafter referred to as a first region R1 of the first electrode E110, which is in contact with or adjacent to the HfₓZr₁₋ₓO_{y} layer L110, may include Bi oxide n11, and the Bi oxide n11 may be present along a grain boundary within the first region R1.

The first region R1 may have a predetermined thickness on a surface portion of the first electrode E110. For example, the first region R1 may have a thickness in the range of about 0.1 nm to 30 nm. The first region R1 may be in contact with the HfₓZr₁₋ₓO_{y} layer L110. The first electrode E110 may have a polycrystalline structure, and the Bi oxide n11 may be present along the grain boundaries of the first electrode E110. The Bi oxide n11 may include, for example, Bi₂O₃.

The materials of the first electrode E110, the second electrode E210, and the HfₓZr₁₋ₓO_{y} layer L110 may correspond to the materials of the first electrode E10, the second electrode E20, and the HfₓZr₁₋ₓO_{y} layer L10 described with reference to FIG. 1, respectively.

In this embodiment, the Bi oxide n11 may infiltrate into the first region R1 of the first electrode E110. The infiltration of the Bi oxide n11 may cure defects at the grain boundary of the first electrode E110. The Bi oxide n11 may contribute to reducing leakage current by curing grain boundaries. In addition, the Bi oxide n11 may cure defects at interfaces. In addition, the Bi oxide n11 may enhance the crystallinity of the HfₓZr₁₋ₓO_{y} layer L110 to increase the dielectric constant. Furthermore, the Bi oxide n11 may increase the dielectric constant by inducing stress in the grains at the interface between the dielectric layer (HfₓZr₁₋ₓO_{y} layer L110) and the first electrode E110, which may also contribute to an increase in the dielectric constant. As a result, the Bi oxide n11 may simultaneously provide the effects of enhanced permittivity and reduced leakage current. Although not shown in FIG. 17, Bi oxide disposed along a grain boundary may also be present in certain regions of the HfₓZr₁₋ₓO_{y} layer L110 that are in contact with or adjacent to the first electrode E110.

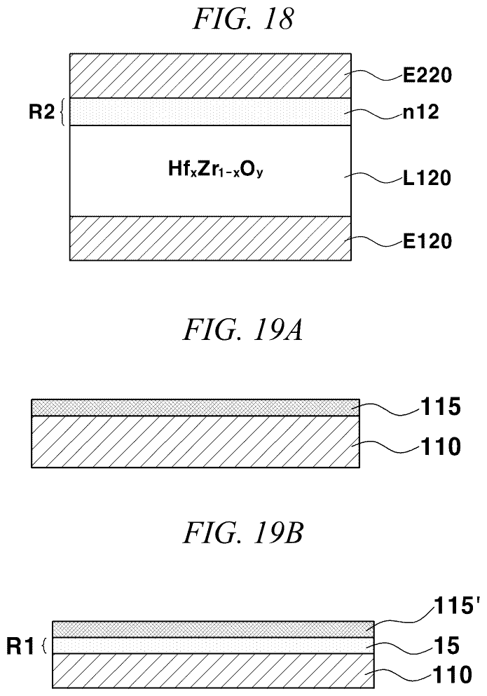

FIG. 18 illustrates a cross-sectional view of a capacitor according to another embodiment of the present disclosure.

Referring to FIG. 18, the capacitor may include a first electrode E120, a second electrode E220 disposed spaced apart from the first electrode E120, and an HfₓZr₁₋ₓO_{y} layer L120 disposed between the first electrode E120 and the second electrode E220, wherein x may satisfy 0≤x≤1, and y may satisfy 1.5<y≤2. A region (hereinafter referred to as a second region R2) of the HfₓZr₁₋ₓO_{y} layer L120, which is in contact with or adjacent to the second electrode E220, may include Bi oxide n12, and the Bi oxide n12 may be present along a grain boundary within the second region R2.

The second region R2 may have a predetermined thickness at a surface portion of the HfₓZr₁₋ₓO_{y} layer L120. For example, the second region R2 may have a thickness in the range of about 0.1 nm to 30 nm. The second region R2 may be in contact with the second electrode E220. The HfₓZr₁₋ₓO_{y} layer L120 may have a polycrystalline structure, and the Bi oxide n12 may be present along the grain boundaries of the HfₓZr₁₋ₓO_{y} layer L120. The Bi oxide n12 may include, for example, Bi₂O₃.

The materials of the first electrode E120, the second electrode E220, and the HfₓZr₁₋ₓO_{y} layer L120 may correspond to the materials of the first electrode E10, the second electrode E20, and the HfₓZr₁₋ₓO_{y} layer L10 described with reference to FIG. 1, respectively.

In this embodiment, the Bi oxide n12 may infiltrate into the second region R2 of the HfₓZr₁₋ₓO_{y} layer L120. The infiltration of the Bi oxide n12 may cure the defects at the grain boundaries of the HfₓZr₁₋ₓO_{y} layer L120. The Bi oxide n12 may reduce the leakage current by curing grain boundaries. In addition, the Bi oxide n12 may cure defects at interfaces. In addition, the Bi oxide n12 may enhance the crystallinity of the HfₓZr₁₋ₓO_{y} layer L120 to increase the dielectric constant. Furthermore, the Bi oxide n12 may increase the dielectric constant by inducing stress in the grains at the interface between the HfₓZr₁₋ₓO_{y} layer L120, which is the dielectric layer, and the second electrode E220. As a result, the Bi oxide n12 may simultaneously provide the effects of enhanced permittivity and reduced leakage current. Although not shown in FIG. 18, Bi oxide n12 disposed along a grain boundary may also be present in certain regions of the second electrode E220 that are in contact with or adjacent to the HfₓZr₁₋ₓO_{y} layer. In addition, according to another embodiment, the first electrode E120 of FIG. 18 may also include the Bi oxide n11 described in FIG. 17.

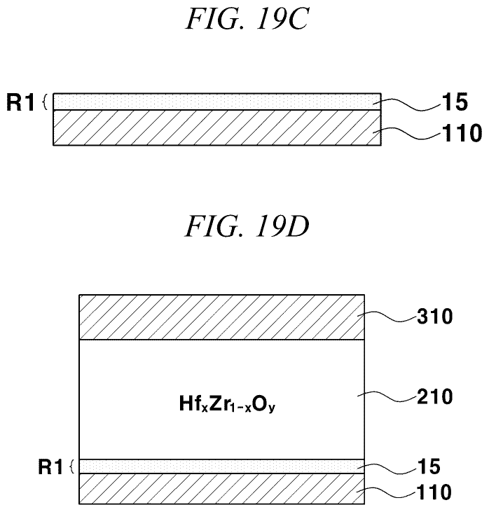

FIGS. 19A through 19D illustrate cross-sectional views for a method of fabricating a capacitor according to another embodiment of the present disclosure.

Referring to FIG. 19A, a first electrode 110 may be provided, and a Bi oxide layer 115 may be formed on the first electrode 110. The Bi oxide layer 115 may include, for example, Bi₂O₃. The Bi oxide layer 115 may be a Bi₂O₃ layer.

Referring to FIG. 19B, annealing may be performed on the first electrode 110 and the Bi oxide layer 115 such that the Bi oxide from the Bi oxide layer 115 infiltrates into a region (hereinafter referred to as a first region R1) of the first electrode 110 and becomes disposed along the grain boundaries. Reference numeral 15 denotes the Bi oxide that has infiltrated into the first region R1, and reference numeral 115′ denotes the remaining portion of the Bi oxide layer 115 on the first electrode 110.

According to one embodiment, the annealing may be performed in an inert gas atmosphere to a temperature in the range of about 300 to 550° C. The inert gas may include, as a non-limiting example, N2 gas. Under these temperature conditions, the penetration of Bi oxide may be facilitated.

Referring to FIG. 19C, at least a portion or all of the Bi oxide layer (115′ in FIG. 19B) remaining on the first electrode 110 may be removed. The Bi oxide layer (115′ in FIG. 19B) remaining on the first electrode 110 may be removed, for example, using an atomic layer etching (ALE) process. The ALE process may enable selective removal of the Bi oxide layer (115′ in FIG. 19B) without damaging the first electrode 110.

Referring to FIG. 19D, an HfₓZr₁₋ₓO_{y} layer 210 may be formed on the first electrode 110 including the Bi oxide 15. Here, x may satisfy 0≤x≤1, and y may satisfy 1.5<y≤2. Then, a second electrode 310 may be formed on the HfₓZr₁₋ₓO_{y} layer 210.

Before or after the step of forming the second electrode 310, a heat treatment may be performed on the laminated structure including at least the first electrode 110 and the HfₓZr₁₋ₓO_{y} layer 210. The heat treatment may be performed at a temperature of, for example, about 1000° C. or less. The resulting product of the manufacturing method of FIGS. 19A to 19D may correspond to the capacitor described with reference to FIG. 17.

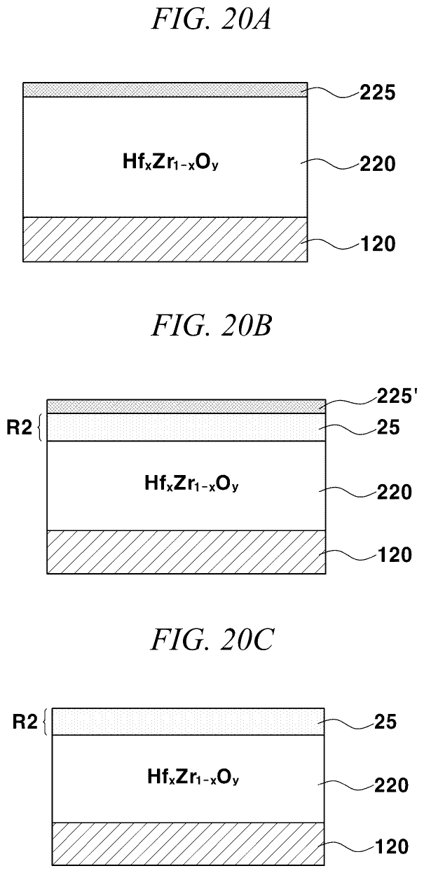

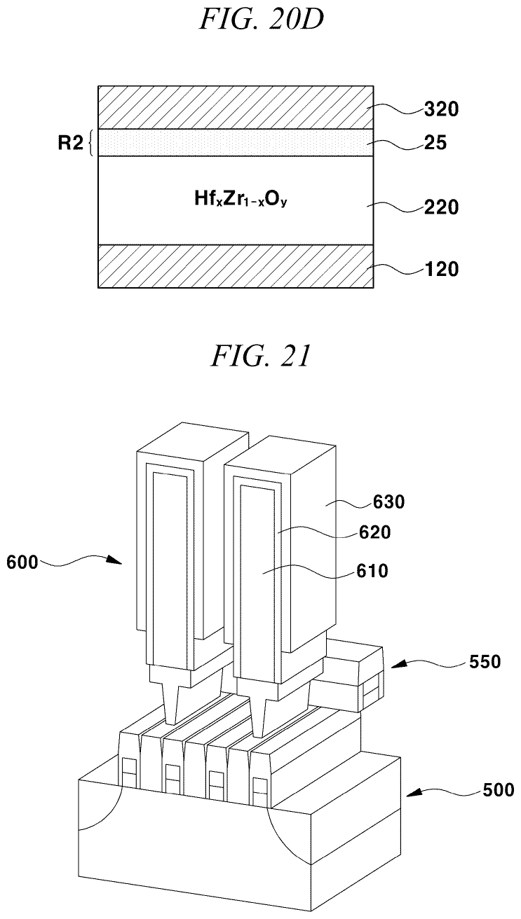

FIGS. 20A through 20D illustrate cross-sectional views for a method of fabricating a capacitor according to another embodiment of the present disclosure.

Referring to FIG. 20A, a first electrode 120 may be provided, and a HfₓZr₁₋ₓO_{y} layer 220 may be formed on the first electrode 120. Here, x may satisfy 0≤x≤1, and y may satisfy 1.5<y≤2. Then, a Bi oxide layer 225 may be formed on the HfₓZr₁₋ₓO_{y} layer 220. The Bi oxide layer 225 may include, for example, Bi₂O₃. The Bi oxide layer 225 may be a Bi₂O₃ layer.

Referring to FIG. 20B, annealing may be performed on the HfₓZr₁₋ₓO_{y} layer 220 and the Bi oxide layer 225 such that the Bi oxide from the Bi oxide layer 225 infiltrates into a region (hereinafter referred to as a second region R2) of the HfₓZr₁₋ₓO_{y} layer 220 and becomes disposed along the grain boundaries. Reference numeral 25 denotes the Bi oxide that has infiltrated into the second region R2, and reference numeral 225′ denotes the remaining portion of the Bi oxide layer 225 on the HfₓZr₁₋ₓO_{y} layer 220.

According to one embodiment, the annealing may be performed in an inert gas atmosphere to a temperature in the range of about 300 to 550° C. The inert gas may include, as a non-limiting example, N2 gas. Under these temperature conditions, the penetration of the Bi oxide may be facilitated.

Referring to FIG. 20C, at least a portion or all of the Bi oxide layer (225′ in FIG. 20B) remaining on the HfₓZr₁₋ₓO_{y} layer 220 may be removed. The Bi oxide layer (225′ in FIG. 20B) remaining on the HfₓZr₁₋ₓO_{y} layer 220 may be removed, for example, using an atomic layer etching (ALE) process. The ALE process may enable selective removal of the Bi oxide layer (225′ in FIG. 20B) without damaging the HfₓZr₁₋ₓO_{y} layer 220.

Referring to FIG. 20D, a second electrode 320 may be formed on the HfₓZr₁₋ₓO_{y} layer 220 including the Bi oxide 25.

Before or after the step of forming the second electrode 320, a heat treatment may be performed on the laminated structure including at least the first electrode 120 and the HfₓZr₁₋ₓO_{y} layer 220. The heat treatment may be performed at a temperature of, for example, about 1000° C. or less. The resulting product of the manufacturing method of FIGS. 20A to 20D may correspond to the capacitor described with reference to FIG. 18.

Optionally, the method of FIGS. 19A to 19D and the method of FIGS. 20A to 20D may be combined. In this case, a capacitor may be formed to include the Bi oxide 15 in the first region R1 and the Bi oxide 25 in the second region R2.

Although an exemplary method of manufacturing the capacitor of FIG. 17 has been described with reference to FIGS. 19A through 19D, and an exemplary method of manufacturing the capacitor of FIG. 18 has been described with reference to FIGS. 20A through 20D, the methods of manufacturing the capacitors of FIGS. 17 and 18 may be varied.

The capacitor structure manufactured according to the embodiment of the present disclosure, i.e., the capacitor structure described in FIGS. 1 to 6, FIG. 17, FIG. 18, and the like, may be applied to various electronic/semiconductor devices. For example, a capacitor according to an embodiment of the present disclosure may be applied to a memory device utilizing a capacitor as a data storage member. Here, the memory device may be a dynamic random access memory (DRAM). In order to apply the capacitor to DRAM, it may be desirable to manufacture the capacitor by an ALD process. Since the capacitor according to an embodiment of the present disclosure may be manufactured by an ALD process, it may be easily applied to a DRAM. In FIGS. 1 to 6, FIG. 17, FIG. 18, and the like, a capacitor is shown with a simple planar structure, but when applied as a capacitor for a DRAM, the capacitor according to an embodiment of the present disclosure may have various modified structures, such as a cylinder shape, a cup shape, and the like.

FIG. 21 illustrates an exemplary configuration of a DRAM device to which a capacitor according to an embodiment of the present disclosure may be applied.

Referring to FIG. 21, the DRAM device may include a cell transistor 500 and a capacitor 600 electrically coupled thereto. The capacitor 600 may include a first electrode 610, a second electrode 630, and a dielectric layer 620 disposed therebetween. The first electrode 610 may be a lower electrode, and the second electrode 630 may be an upper electrode. The capacitor 600 may exhibit any of the characteristics described in the foregoing embodiments. However, the structure of the capacitor 600 illustrated in FIG. 21 is provided for exemplary purposes only and may be varied. The capacitors according to embodiments of the present disclosure may be applied to any capacitor structure used in conventional DRAM devices. When the capacitor according to an embodiment of the present disclosure is applied to a DRAM, it may provide advantages in terms of improved integration density and enhanced device performance. In addition, the capacitor according to an embodiment of the present disclosure may be applied to other memory devices or various electronic/semiconductor devices beyond DRAM. In FIG. 21, reference numeral 550 denotes a bitline, which is not separately described.

A method of fabricating an electronic device, e.g., a memory device according to embodiments of the present disclosure, may include a method of fabricating a capacitor according to any of the foregoing embodiments.

According to the embodiments of the present disclosure described above, it is possible to realize a capacitor capable of simultaneously improving the dielectric constant of a dielectric layer and reducing the leakage current. According to one embodiment, the dielectric permittivity may be increased by improving the crystallinity of the dielectric layer HfₓZr₁₋ₓO_{y} layer through the insertion of the Bi₂O₃ material, and the leakage current characteristics may be improved by reducing the oxygen vacancies in the dielectric layer HfₓZr₁₋ₓO_{y} layer due to the present of the Bi₂O₃ material. In addition, according to embodiments of the present disclosure, a capacitor may be implemented that may reduce the leakage current by curing defects at the grain boundaries of the electrode or dielectric layer, and may increase the dielectric constant by inducing stress in the grains at the interface between the dielectric layer and the electrode. According to one embodiment, infiltrating Bi oxide into a surface portion of the first electrode or a surface portion of the dielectric layer HfₓZr₁₋ₓO_{y} layer can cure defects within the grain structure and induce stress in the grains at the interface between the electrode and the dielectric layer, thereby reducing leakage current and increasing dielectric constant. The capacitors according to embodiments of the present disclosure may be usefully applied to electronic devices, for example, memory devices such as DRAM, which may advantageously improve the integration and performance of the memory devices.

This description discloses preferred embodiments of the present disclosure, and although certain terms are used, they are used in a general sense only to facilitate the description and understanding of the disclosure and are not intended to limit the scope of the disclosure. In addition to the embodiments disclosed herein, other modifications based on the technical ideas of the present disclosure will be apparent to those of ordinary skill in the art to which the present disclosure belongs. One having ordinary knowledge in the art will recognize that the capacitors, methods of manufacturing the capacitors, electronic devices including the capacitors, and methods of manufacturing electronic devices according to the embodiments described with reference to FIGS. 1 through 21 may be subject to various substitutions, changes, and modifications without departing from the technical ideas of the present disclosure. As a specific example, it will be appreciated that the HfₓZr₁₋ₓO_{y} layer may be doped with a predetermined doping material, and that a separate layer of dielectric material in addition to the HfₓZr₁₋ₓO_{y} layer may be applied to the capacitor. The scope of the disclosure is not to be limited by the embodiments described, but rather by the technical ideas recited in the patent claims.

What is claimed is:

1. A capacitor, comprising:
a first electrode;
a second electrode disposed spaced apart from the first electrode; and
a laminated film disposed between the first electrode and the second electrode,
wherein the laminated film comprises:
HfₓZr₁₋ₓO_{y} layer, where x satisfies 0≤x≤1 and y satisfies 1.5<y≤2; and
a Bi₂O₃ layer disposed in one or more of:
a region between the first electrode and the HfₓZr₁₋ₓO_{y} layer;
a region between the second electrode and the HfₓZr₁₋ₓO_{y} layer; and
an intermediate region of the HfₓZr₁₋ₓO_{y} layer in a direction in which the first and second electrodes are spaced apart each other.

2. The capacitor of claim 1, wherein the HfₓZr₁₋ₓO_{y} layer has a structure selected from the group consisting of: a monolayer of Zr oxide, a monolayer of Hf oxide, a mixed layer including Zr oxide and Hf oxide, and a laminated structure in which Zr oxide and Hf oxide layers are alternately stacked.

3. The capacitor of claim 1, wherein the Bi₂O₃ layer has a thickness in a range of 0.001 nm to 3 nm.

4. The capacitor of claim 1, wherein the laminated film has a thickness in a range of 3 nm to 30 nm.

5. The capacitor of claim 1, wherein, when the HfₓZr₁₋ₓO_{y} layer includes a first HfₓZr₁₋ₓO_{y} layer disposed in contact with or adjacent to the first electrode and a second HfₓZr₁₋ₓO_{y} layer disposed in contact with or adjacent to the second electrode, and the Bi₂O₃ layer is disposed in the intermediate region of the HfₓZr₁₋ₓO_{y} layer, the Bi₂O₃ layer is disposed between the first and second HfₓZr₁₋ₓO_{y} layers.

6. The capacitor of claim 1, wherein the Bi₂O₃ layer is configured to reduce oxygen vacancies in the HfₓZr₁₋ₓO_{y} layer.

7. The capacitor of claim 1, wherein the Bi₂O₃ layer is configured to increase a dielectric constant of the HfₓZr₁₋ₓO_{y} layer.

8. A memory device comprising the capacitor of claim 1 as a data storage element.

9. A capacitor, comprising:
a first electrode;
a second electrode disposed spaced apart from the first electrode; and
a HfₓZr₁₋ₓO_{y} layer disposed between the first electrode and the second electrode, wherein x satisfies 0≤x≤1 and y satisfies 1.5<y≤2,
wherein Bi oxide is present in one or both of:
a first region of the first electrode that is in contact with or adjacent to the HfₓZr₁₋ₓO_{y} layer; and
a second region of the HfₓZr₁₋ₓO_{y} layer that is in contact with or adjacent to the second electrode,
wherein the Bi oxide is disposed along a grain boundary within one or both of the first and second regions.

10. The capacitor of claim 9, wherein the HfₓZr₁₋ₓO_{y} layer has a structure selected from the group consisting of: a monolayer of Zr oxide, a monolayer of Hf oxide, a mixed layer including Zr oxide and Hf oxide, and a laminated structure in which Zr oxide and Hf oxide layers are alternately stacked.

11. The capacitor of claim 9, wherein the first region has a thickness in a range of 0.1 nm to 30 nm.

12. The capacitor of claim 9, wherein the second region has a thickness in a range of 0.1 nm to 30 nm.

13. The capacitor of claim 9, wherein the Bi oxide is configured to increase a dielectric constant of the HfₓZr₁₋ₓO_{y} layer.

14. A memory device comprising the capacitor of claim 9 as a data storage member.

15. A method of manufacturing a capacitor, the method comprising:
providing a first electrode;
forming a Bi oxide layer on the first electrode;
performing annealing on the first electrode and the Bi oxide layer such that Bi oxide from the Bi oxide layer infiltrates into a boundary region of the first electrode along a grain boundary;
removing at least a portion of the Bi oxide layer remaining on the first electrode after the annealing;
forming a HfₓZr₁₋ₓO_{y} layer over the first electrode comprising the infiltrated Bi oxide, wherein x satisfies 0≤x≤1 and y satisfies 1.5<y≤2; and
forming a second electrode on the HfₓZr₁₋ₓO_{y} layer.

16. The method of claim 15, wherein the annealing is performed at a temperature of 300 to 550° C. in an inert gas atmosphere.

17. The method of claim 15, wherein the removing at least a portion of the Bi oxide layer is performed by an atomic layer etching (ALE) process.

18. The method of claim 15, further comprising:
performing a heat treatment on a laminated structure comprising at least the first electrode and the HfₓZr₁₋ₓO_{y} layer, either before or after the forming a second electrode.

19. A method of manufacturing a capacitor, the method comprising:
providing a first electrode;
forming a HfₓZr₁₋ₓO_{y} layer on the first electrode, wherein x satisfies 0≤x≤1 and y satisfies 1.5<y≤2;
forming a Bi oxide layer on the HfₓZr₁₋ₓO_{y} layer;
performing annealing on the HfₓZr₁₋ₓO_{y} layer and the Bi oxide layer such that Bi oxide from the Bi oxide layer infiltrates into a boundary region of the HfₓZr₁₋ₓO_{y} layer along grain boundaries;
removing at least a portion of the Bi oxide layer remaining on the HfₓZr₁₋ₓO_{y} layer after the annealing; and
forming a second electrode over the HfₓZr₁₋ₓO_{y} layer comprising the infiltrated Bi oxide.

20. The method of claim 19, wherein the annealing is performed at a temperature of 300 to 550° C. in an inert gas atmosphere.

21. The method of claim 19, wherein the removing at least a portion of the Bi oxide layer is performed by an atomic layer etching (ALE) process.

22. The method of claim 19, further comprising:
performing a heat treatment on a laminated structure comprising at least the first electrode and the HfₓZr₁₋ₓO_{y} layer, either before or after the forming a second electrode.
